(19) United States
(12) Patent Application Publication
(10) Pub. No.: US 2015/0107640 A1
(43) Pub. Date: Apr. 23, 2015

(54) IV-VI AND III-V QUANTUM DOT STRUCTURES IN A V-VI MATRIX

(71) Applicant: Phononic Devices, Inc., Durham, NC (US)

(72) Inventors: James Christopher Caylor, Chapel Hill, NC (US); Ian Patrick Wellenius, Raleigh, NC (US); William O. Charles, Morrisville, NC (US); Pablo Cantu, Raleigh, NC (US); Allen L. Gray, Holly Springs, NC (US)

(21) Appl. No.: 14/517,345

(22) Filed: Oct. 17, 2014

Related U.S. Application Data
(60) Provisional application No. 61/894,589, filed on Oct. 23, 2013.

(51) Int. Cl. H01L 35/16; H01L 35/34; H01L 35/18

(52) U.S. Cl. CPC H01L 35/16; H01L 35/18; H01L 35/34
USPC 136/238; 438/54

(57) ABSTRACT

A thermoelectric material and methods of manufacturing thereof are disclosed. In general, the thermoelectric material comprises a Group V-VI host, or matrix, material and Group III-V or Group IV-VI nanoinclusions within the Group V-VI host material. By incorporating the Group III-V or Group IV-VI nanoinclusions into the Group V-VI host material, the performance of the thermoelectric material can be improved.

### RELATED APPLICATIONS

This application claims the benefit of provisional patent application serial number 61/894,589, filed Oct. 23, 2013, the disclosure of which is hereby incorporated herein by reference in its entirety.

### FIELD OF THE DISCLOSURE

The present disclosure relates to thermoelectric materials.

### BACKGROUND

A thermoelectric device can be used as a thermoelectric power generator or a thermoelectric cooler. Applications of these devices range from, for example, electronic thermal management and solid state refrigeration to power generation from waste heat sources. A thermoelectric generator is a solid state thermoelectric device that provides direct energy conversion from thermal energy (heat) due to a temperature gradient into electrical energy based on a so-called “Seebeck effect.” Likewise, a thermoelectric cooler is a solid state thermoelectric device that uses the “Peltier effect” to transfer heat from one side of the device to the other with the consumption of electrical energy. The thermoelectric power cycle, with charge carriers (electrons) serving as the working fluid, follows the fundamental laws of thermodynamics and intimately resembles the power cycle of a conventional heat engine. Thermoelectric devices offer several distinct advantages over other technologies including, for example, high reliability, small footprint but with potential scaling to meet large area applications, lightweight, flexibility, and non-position dependency.

A major challenge of thermoelectric devices is their relatively low conversion efficiency, which is typically ˜5%. This has been a major cause in restricting their use to specialized fields where space and reliability are a premium.

The figure-of-merit (ZT) of a thermoelectric material is a dimensionless unit that is used to compare the efficiencies of various materials. ZT is determined by three physical parameters: thermopower a (also known as a Seebeck coefficient), electrical conductivity a, and thermal conductivity k=kₑ+kₚₕ, where kₑ and kₚₕ are the contributions to thermal conductivity by charge carriers (electrons and holes) and phonons, respectively; and absolute temperature T:

$$ZT = \frac{{α}^{2} σ}{( {k}_{e} + {k}_{p h} )} T .$$

Maximum ZT in bulk thermoelectric materials is governed by the intrinsic properties of the material system. Most candidates require low thermal conductivity as the driving force for enhanced ZT because of the inverse relationship between the Seebeck coefficient and electrical conductivity. This interdependence and coupling between the Seebeck coefficient and the electrical conductivity makes it difficult to increase ZT>1, despite nearly five decades of research. Increasing this value to 2.0 or higher will disrupt existing technologies and will ultimately enable more widespread use of thermoelectric systems.

Thus, there is a need for a thermoelectric material having improved performance.

### SUMMARY

A thermoelectric material and methods of manufacturing thereof are disclosed. In general, the thermoelectric material comprises a Group V-VI host, or matrix, material and Group III-V or Group IV-VI nanoinclusions within the Group V-VI host material. As used herein, a “nanoinclusion” is, as understood by those of ordinary skill in the art, a nano-sized physical inclusion that may or may not affect thermal and/or electrical transport properties of the thermoelectric material. In one embodiment, the nanoinclusions are quantum dots, where, as used herein, a “quantum dot” is a nanoinclusion where the spatial dimensions of the nanoinclusion may also lead to unique properties that are dissimilar from the macroscale material of which the quantum dot is formed. By incorporating the Group III-V or Group IV-VI nanoinclusions into the Group V-VI host material, the performance of the thermoelectric material can be improved.

In one embodiment, the nanoinclusions comprise nanoinclusions of Indium Antimonide (InSb) or an alloy thereof. In one embodiment, the nanoinclusions comprise nanoinclusions of the alloy of InSb, and the alloy of InSb is In_{1-X}Ga_{X}Sb, where 0<X<1. In another embodiment, the nanoinclusions comprise nanoinclusions of Lead Telluride (PbTe) or an alloy thereof. In one embodiment, the nanoinclusions comprise nanoinclusions of the alloy of PbTe, and the alloy of PbTe is PbTe_{1-X}Se_{X}, Pb_{1-X}Ge_{X}Te_{Y}Se_{1-Y}, Pb_{1-X}Sn_{X}Te_{Y}Se_{1-Y}, or Pb_{1-X}Sr_{X}Te_{Y}Se_{1-Y}, where 0<X<1 and where 0<Y<1.

In one embodiment, the Group V-VI host material is Bismuth Telluride (Bi₂Te₃) or an alloy of Bi₂Te₃. Further, in one embodiment, the Group V-VI host material is Bi₂Te₃ or an alloy of Bi₂Te₃, and the nanoinclusions comprise nanoinclusions of InSb or an alloy thereof. In another embodiment, the Group V-VI host material is Bi₂Te₃ or an alloy of Bi₂Te₃, and the nanoinclusions comprise nanoinclusions of PbTe or an alloy thereof.

In one embodiment, the Group V-VI host material is Antimony Telluride (Sb₂Te₃) or an alloy of Sb₂Te₃. Further, in one embodiment, the Group V-VI host material is Sb₂Te₃ or an alloy of Sb₂Te₃, and the nanoinclusions comprise nanoinclusions of InSb or an alloy thereof. In another embodiment, the Group V-VI host material is Sb₂Te₃ or an alloy of Sb₂Te₃, and the nanoinclusions comprise nanoinclusions of PbTe or an alloy thereof.

In one embodiment, the Group V-VI host material is Bismuth Antimony Telluride (Bi_{X}Sb_{2-X}Te₃) or an alloy of Bi_{X}Sb_{2-X}Te₃. Further, in one embodiment, the Group V-VI host material is Bi_{X}Sb_{2-X}Te₃ or an alloy of Bi_{X}Sb_{2-X}Te₃, and the nanoinclusions comprise nanoinclusions of InSb or an alloy thereof. In another embodiment, the Group V-VI host material is Bi_{X}Sb_{2-X}Te₃ or an alloy of Bi_{X}Sb_{2-X}Te₃, and the nanoinclusions comprise nanoinclusions of PbTe or an alloy thereof.

In another embodiment, the Group V-VI host material is Bismuth

Telluride-Selenide (Bi₂Te_{3-X}Se_{X}) or an alloy of Bi₂Te_{3-X}Se_{X}. Further, in one embodiment, the Group V-VI host material is Bi₂Te_{3-X}Se_{X} or an alloy of Bi₂Te_{3-X}Se_{X}, and the nanoinclusions comprise nanoinclusions of InSb or an alloy thereof. In another embodiment, the Group V-VI host material is Bi₂Te_{3-X}Se_{X} or an alloy of Bi₂Te_{3-X}Se_{X}, and the nanoinclusions comprise nanoinclusions of PbTe or an alloy thereof.

In one embodiment, a lattice mismatch between the Group V-VI host material and a material used for the nanoinclusions is greater than 4%. In another embodiment, a lattice mismatch between the Group V-VI host material and a material used for the nanoinclusions is greater than 5%. In another embodiment, a lattice mismatch between the Group V-VI host material and a material used for the nanoinclusions is greater than 6%. In another embodiment, a lattice mismatch between the Group V-VI host material and a material used for the nanoinclusions is greater than 7%.

In one embodiment, the nanoinclusions form a random structure within the Group V-VI host material. In another embodiment, the nanoinclusions form an ordered structure within the Group V-VI host material.

In one embodiment, a method of fabricating a thermoelectric material is provided. The method includes providing a first layer of a Group V-VI host material, depositing a layer of nanoinclusions on a surface of the first layer of the Group V-VI host material, and depositing a second layer of the Group V-VI host material over the layer of nanoinclusions. The nanoinclusions comprise Group III-V nanoinclusions or Group IV-VI nanoinclusions. In one embodiment, the method further comprises depositing a second layer of nanoinclusions on a surface of the second layer of the Group V-VI host material, and depositing third layer of the Group V-VI host material over the second layer of nanoinclusions.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 illustrates a thermoelectric material according to one embodiment of the present disclosure;

FIGS. 2A through 2I illustrate a process for fabricating the thermoelectric material of FIG. 1 according to one embodiment of the present disclosure;

FIG. 3 illustrates a thermoelectric material according to another embodiment of the present disclosure; and

FIGS. 4A through 4I illustrate a process for fabricating the thermoelectric material of FIG. 3 according to one embodiment of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

Embodiments of a thermoelectric material and methods of manufacturing, or fabricating, the thermoelectric material are disclosed. In general, the thermoelectric material comprises a Group V-VI host, or matrix, material and Group III-V or Group IV-VI nanoinclusions within the Group III-V host material. As used herein, a “nanoinclusion” is, as understood by those of ordinary skill in the art, a nano-sized physical inclusion that may or may not affect thermal and/or electrical transport properties of the thermoelectric material. In one embodiment, the nanoinclusions are quantum dots, where, as used herein, a “quantum dot” is a nanoinclusion where the spatial dimensions of the nanoinclusion may also lead to unique properties that are dissimilar from the macroscale material of which the quantum dot is formed.

By incorporating the Group III-V or Group IV-VI inclusions into the Group V-VI host material, the performance of the thermoelectric material can be improved. In other words, the thermoelectric performance of the material can be improved, or enhanced, via the nanostructures, i.e., the nanoinclusions. As described below, the thermoelectric material may be fabricated using material deposition techniques (e.g., Molecular Beam Epitaxy (MBE), Metal-Organic Chemical Vapor Deposition (MOCVD), etc.) to enable control of the nanostructures at a nanometer scale. During fabrication, lattice-mismatch induced strain and stress enable nanostructures in thermoelectrically relevant materials systems, e.g., Group III-V, Group IV-VI, and Group V-VI compounds. A Group V-VI material (i.e., a compound or alloy) such as, for example, Bismuth Telluride (Bi₂Te₃), Antimony Telluride (Sb₂Te₃), Bismuth Antimony Telluride (Bi_{X}Sb_{2-X}Te₃), or Bismuth Telluride-Selenide (Bi₂Te_{3-X}Se_{X}) is used as a host, or matrix, material, and a Group III-V or Group IV-VI material (compound or alloy) of thermal relevancy is used for the nanoinclusions. The lattice mismatch between the materials used for the host material and the nanoinclusions is preferably greater than 4%, greater than 5%, greater than 6%, or greater than 7% in order to induce the nanoinclusions (e.g., quantum dots). Specifically, the use of a lattice mismatch of greater than 4-5% will induce changes in the growth mode of materials from a two-dimensional, Frank-van der Merwe, mode to either a fully three dimensional (3D) mode, such as Volmer-Weber, or an intermediate mode, such as Stranski-Krastanov, where 3D islands can grow after a thin two dimensional (2D) layer is formed. The 3D growth is controlled to a layer with the 3D “dots” or inclusions limited in size to nanometer (nm) scale. In some embodiments, the inclusions are then covered with one or more layers of a Group V-VI or other material to return the film to 2D growth mode before the next layer of inclusions are initiated.

While not being limited to any particular type of activity, the activity of the nanoinclusions may include, for example:
Quantum Dots: Changes in band structures associated with the nanoinclusions.
Modulation Doping: The nanoinclusions may enable spatial decouping of charge carriers from their respective dopant ions, reducing charge carrier scattering due to ionized impurities.
Energy Filtering: The nanoinclusions may provide scattering of carriers depending on energy due to the local band structure, geometry, or dislocations associated with the nanoinclusions.
Phonon Scattering: The nanoinclusions may provide scattering of phonons by mass difference, grain structure, or dislocations associated with the nanoinclusions.

Table 1 below shows some examples of Group III-V and Group IV-VI materials and their lattice mismatch with some examples of Group V-VI materials having good thermoelectric properties. Here, lattice mismatch refers to the difference in the in-plane atomic spacing between two adjoining epitaxial layers. The degree of mismatch is determined by comparing the distance between the parallel (110) atomic planes of the (111)-oriented cubic crystal to that of the in-plane lattice parameter “a” of the (001)-oriented hexagonal crystal. The (110) plane spacing is determined from the cubic lattice parameter “a.” Here, the crystal orientation refers to the lattice vector normal to the surface of the deposited material. Table 1 is used to show the close relative atomic/lattice registration of the relevant in-plane atomic spacings between the cubic and hexagonal crystals for a number of suitable thermoelectric materials.

TABLE 1

| | | | | | Lattice | Lattice | Lattice | Lattice |
|---|---|---|---|---|---|---|---|---|
| | | | | Cubic | Mismatch | Mismatch | Mismatch with | Mismatch with |
| | | | Lattice | (110) | with Sb₂Te₃ | with Bi₂Te₃ | Bi_{0.5}Sb_{1.5}Te₃ | Bi₂Te_{2.7}Se_{0.3} |
| | | Crystal | Parameter | Plane | (%) | (%) | (%) | (%) |
| Material | Group | Structure | ″a″ (Å) | Spacing | (a = 4.25 Å) | (a = 4.38 Å) | (a = 4.28 Å) | (a = 4.36 Å) |
| Bi₂Te₃ | V-VI | Hex | 4.38 | | 3.1% | 0.0% | 2.3% | 0.6% |
| Sb₂Te₃ | V-VI | Hex | 4.25 | | 0.0% | −3.0% | −0.7% | −2.4% |
| Bi₂Se₃ | V-VI | Hex | 4.14 | | −2.6% | −5.5% | −3.3% | −4.9% |
| PbTe | IV-VI | FCC | 6.45 | 4.56 | 7.3% | 4.1% | 6.6% | 4.7% |
| PbSe | IV-VI | FCC | 6.12 | 4.33 | 1.8% | −1.2% | 1.1% | −0.6% |
| GeTe | IV-VI | FCC | 5.98 | 4.23 | −0.5% | −3.5% | −1.2% | −2.9% |
| SnTe | IV-VI | FCC | 6.31 | 4.46 | 5.0% | 1.9% | 4.2% | 2.5% |
| InSb | III-V | FCC | 6.48 | 4.58 | 7.8% | 4.6% | 7.1% | 5.2% |
| GaSb | III-V | FCC | 6.09 | 4.31 | 1.3% | −1.7% | 0.6% | −1.1% |

As can be seen from Table 1, the lattice mismatches of both Indium Antimonide (InSb) and Lead Telluride (PbTe) with each of Sb₂Te₃, Bi₂Te₃, Bi_{0.5}Sb_{1.5}Te₃, and Bi₂Te_{2.7}Se_{0.3} is greater than 4%. As such, PbTe and InSb are, in some embodiments, used as the material for the nanoinclusions (e.g., quantum dots) in the Group V-VI host material, which may be, e.g., Bi₂Te₃, Sb₂Te₃, Bi_{X}Sb_{2-X}Te₃, or Bi₂Te_{3-X}Se_{X}. Bi_{X}Sb_{2-X}Te₃ and Bi₂Te_{3-X}Se_{X} are known to be the best alloys for thermoelectric performance near room temperature. As such, in some embodiments, the host material is either Bi_{X}Sb_{2-X}Te₃ or Bi₂Te_{3-X}Se_{X}. However, large lattice mismatches exist between PbTe and InSb and the binary compounds Bi₂Te₃ and Sb₂Te₃. As such, in other embodiments, the Group V-VI host material is either Bi₂Te₃ or Sb₂Te₃. Table 2 below shows a range of alloys of the Group III-V and Group IV-VI materials that may be used for the nanoinclusions in the Group V-VI host material. Note that the subscripts X and Y can span from 0 to 1 (i.e., 0<X<1 and 0<Y<1). Importantly, the ability to alloy the base materials for the nanoinclusions, InSb and PbTe in some embodiments, gives tunability of electronic and structural components of the nanoinclusions to maximize the thermoelectric performance of the composite material (i.e., the thermoelectric material including the host material and the nanoinclusions). For example, the alloy PbTe_{1-X}Se_{X} represents one embodiment to further reduce thermal conductivity. In other embodiments, Pb_{1-X}Sn_{X}Te_{Y}Se_{1-Y} and Pb_{1-X}Sr_{X}Te_{Y}Se_{1-Y} alloys enable tuning of electronic band structure of the nanoinclusion to best optimize electronic resistivity and Seebeck coefficient of the composite material.

TABLE 2

| Materials Family | Specific Compound | Included Alloys |
|---|---|---|
| III-V | InSb | In_{1-X}Ga_{X}Sb |
| IV-VI | PbTe | PbTe_{1-X}Se_{X} |
| | PbSe | Pb_{1-X}Ge_{X}Te_{Y}Se_{1-Y} |
| | | Pb_{1-X}Sn_{X}Te_{Y}Se_{1-Y} |
| | | Pb_{1-X}Sr_{X}Te_{Y}Se_{1-Y} |

Thus, in some embodiments, the thermoelectric material includes Group III-V and/or Group IV-VI compounds or alloys (e.g., InSb and/or PbTe and/or their alloys) as nanoinclusions (e.g., quantum dots or similar nanostructures) in a Group V-VI host, or matrix, material consisting of or comprising Bi₂Te₃, Sb₂Te₃, Bismuth Selenide (Bi₂Se₃) or their alloys. In some embodiments, the nanoinclusions (e.g., quantum dots) range in scale, or size, from 1 nm to 1000 nm. Further, in some embodiments, the nanoinclusions form a random structure within the Group V-VI host material. In other embodiments, the nanoinclusions form an ordered structure in the Group V-VI host material. Thus, embodiments of the thermoelectric material may include structures ranging from a bulk-like film of Group V-VI host material with random Group III-V or Group IV-VI inclusions of nanometer-scale size to an ordered superlattice structure of nanoinclusions with order between superlattice layers in a Group V-VI matrix.

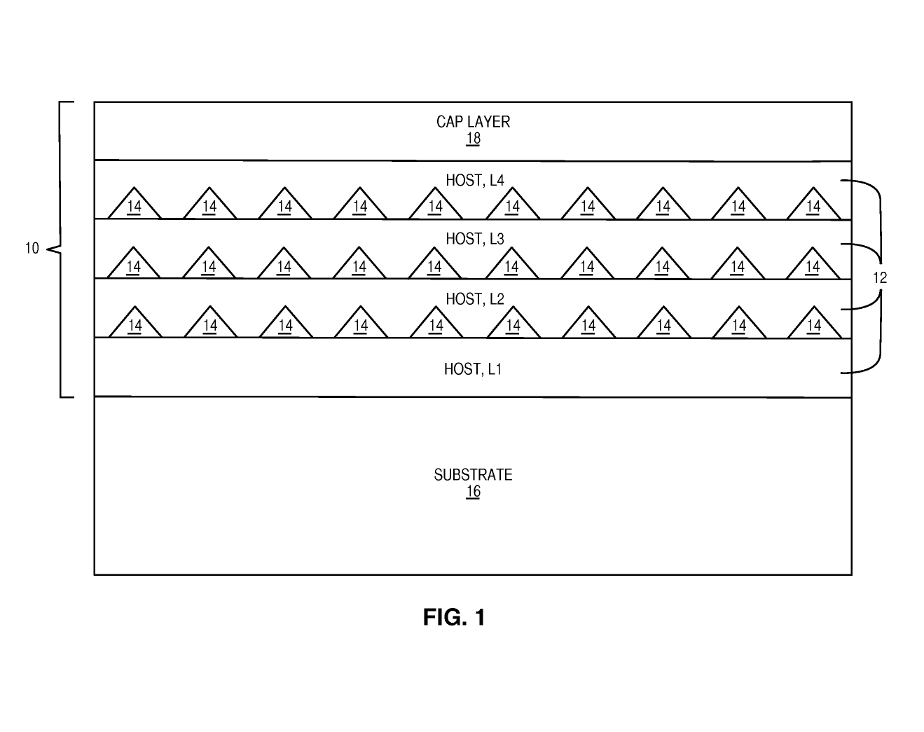

FIG. 1 illustrates a thermoelectric material 10 according to one embodiment of the present disclosure. As illustrated, the thermoelectric material 10 includes a Group V-VI host material 12 and nanoinclusions 14 within the Group V-VI host material 12. The Group V-VI host material 12 may be a bulk-like material or a matrix material having a superlattice structure. The nanoinclusions 14 are formed of a Group III-V and/or a Group IV-VI material. In some embodiments, the materials used for the Group V-VI host material 12 and the nanoinclusions 14 have a lattice mismatch of greater than 4%, greater than 5%, greater than 6%, or greater than 7%, depending on the particular embodiment. As discussed above, a lattice mismatch of greater than 4-5% induces the formation of the nanoinclusions 14 when growing, or depositing, the Group III-V or Group IV-VI material on the Group V-VI material used as the Group V-VI host material 12.

Specifically, in this embodiment, the thermoelectric material 10 is formed on a substrate 16. The substrate 16 may be, for example, GaAs, Si, BaF₂, CaF₂, or another suitable structure. The substrate 16 is treated or pre-processed for a desired crystal orientation, lattice matching, and/or thermal expansion matching. For the lattice mismatch values given in Table 1 above, the substrate 16 is treated or pre-processed for growth of the thermoelectric material 10 in the (001) orientation for hexagonal crystals, such as for the Group V-VI host material 12, or in the (111) orientation for cubic crystals, such as for the nanoinclusions 14. The thermoelectric material 10 includes a first layer L1 of the Group V-VI host material 12 on (in some embodiments directly on) the substrate 16. Note that, while not illustrated, there may be additional layers between the substrate 16 and the first layer L1 of the Group V-VI host material 12 (e.g., a nucleation layer, strain engineering layer(s), or contact layer(s)). The thermoelectric material 10 further includes a first layer of the nanoinclusions 14 on (in some embodiments directly on) the first layer L1 of the Group V-VI host material 12, a second layer L2 of the Group V-VI host material 12 on (in some embodiments directly on) the first layer of the nanoinclusions 14, a second layer of the nanoinclusions 14 on (in some embodiments directly on) the second layer L2 of the Group V-VI host material 12, a third layer L3 of the Group V-VI host material 12 on (in some embodiments directly on) the second layer of the nanoinclusions 14, a third layer of the nanoinclusions 14 on (in some embodiments directly on) the third layer L3 of the Group V-VI host material 12, a fourth layer L4 of the Group V-VI host material 12 on (in some embodiments directly on) the third layer of the nanoinclusions 14, and, in some embodiments, a cap layer 18. The cap layer 18 may, in some embodiments, be formed of a desired contact material. Note that while there are three layers of nanoinclusions 14 in the example of FIG. 1, the thermoelectric material 10 may include any number of one or more (e.g., 1, 10, 100, or more) layers of nanoinclusions 14. It should also be noted that the properties (e.g., physical properties such as size and density) of the nanoinclusions 14 within each layer may be controlled by, e.g., the selection and alloying of the material(s) used for the nanoinclusions 14, the selection and alloying of material(s) used for the Group V-VI host material 12, the thickness of individual layers of the Group V-VI host material 12, the inclusion of any additional layers between the substrate 16 and layer L1 of the Group V-VI host material 12, growth process parameters such as temperature and pressure, or growth interruption at intermediate stages of nanoinclusion formation or modification.

In this embodiment, the nanoinclusions 14 form an ordered structure in which the nanoinclusions 14 in each layer are aligned with the nanoinclusions 14 in the other layers. However, as discussed below, the thermoelectric material 10 is not limited to an ordered structure of nanoinclusions 14. For example, as discussed below, the nanoinclusions 14 may be arranged in a random structure. Further, in this example, the layers of nanoinclusions 14 and the layers of the Group V-VI host material 12 are periodic. However, the thermoelectric material 10 may alternatively be non-periodic, in which case the layers of nanoinclusions 14 are included in the Group V-VI host material 12 in a non-periodic arrangement.

As discussed above, in some embodiments, the Group V-VI host material 12 is Bi₂Te₃, Sb₂Te₃, Bi_{X}Sb_{2-X}Te₃, or Bi₂Te_{3-X}Se_{X}, and the nanoinclusions 14 are a Group III-V or Group IV-VI material such as, e.g., InSb, an alloy of InSb, PbTe, or an alloy of PbTe. Thus, in some embodiments, the Group V-VI host material 12 is Bi₂Te₃, and the nanoinclusions 14 are InSb or an alloy of InSb (e.g., In_{1-X}Ga_{X}Sb, where 0<X<1). In other embodiments, the Group V-VI host material 12 is Bi₂Te₃, and the nanoinclusions 14 are PbTe or an alloy of PbTe (e.g., PbTe_{1-X}Se_{X}, Pb_{1-X}Ge_{X}Te_{Y}Se_{1-Y}, Pb_{1-X}Sn_{X}Te_{Y}Se_{1-Y}, and Pb_{1-X}Sr_{X}Te_{Y}Se_{1-Y}, where 0<X<1 and where 0<Y<1). In some embodiments, the Group V-VI host material 12 is Sb₂Te₃, and the nanoinclusions 14 are InSb or an alloy of InSb (e.g., In_{1-X}Ga_{X}Sb, where 0<X<1). In other embodiments, the Group V-VI host material 12 is Sb₂Te₃, and the nanoinclusions 14 are PbTe or an alloy of PbTe (e.g., PbTe_{1-X}Se_{X}, Pb_{1-X}Ge_{X}Te_{Y}Se_{1-Y}, Pb_{1-X}Sn_{X}Te_{Y}Se_{1-Y}, and Pb_{1-X}Sr_{X}Te_{Y}Se_{1-Y}, where 0<X<1 and where 0<Y<1). In some embodiments, the Group V-VI host material 12 is Bi_{X}Sb_{2-X}Te₃, and the nanoinclusions 14 are InSb or an alloy of InSb (e.g., In_{1-X}Ga_{X}Sb, where 0<X<1). In other embodiments, the Group V-VI host material 12 is Bi_{X}Sb_{2-X}Te₃, and the nanoinclusions 14 are PbTe or an alloy of PbTe (e.g., PbTe_{1-X}Se_{X}, Pb_{1-X}Ge_{X}Te_{Y}Se_{1-Y}, Pb_{1-X}Sn_{X}Te_{Y}Se_{1-Y}, and Pb_{1-X}Sr_{X}Te_{Y}Se_{1-Y}, where 0<X<1 and where 0<Y<1). In some embodiments, the Group V-VI host material 12 is Bi₂Te_{3-X}Se_{X}, and the nanoinclusions 14 are InSb or an alloy of InSb (e.g., In_{1-X}Ga_{X}Sb, where 0<X<1). In other embodiments, the Group V-VI host material 12 is Bi₂Te_{3-X}Se_{X}, and the nanoinclusions 14 are PbTe or an alloy of PbTe (e.g., PbTe_{1-X}Se_{X}, Pb_{1-X}Ge_{X}Te_{Y}Se_{1-Y}, Pb_{1-X}Sn_{X}Te_{Y}Se_{1-Y}, and Pb_{1-X}Sr_{X}Te_{Y}Se_{1-Y}, where 0<X<1 and where 0<Y<1).

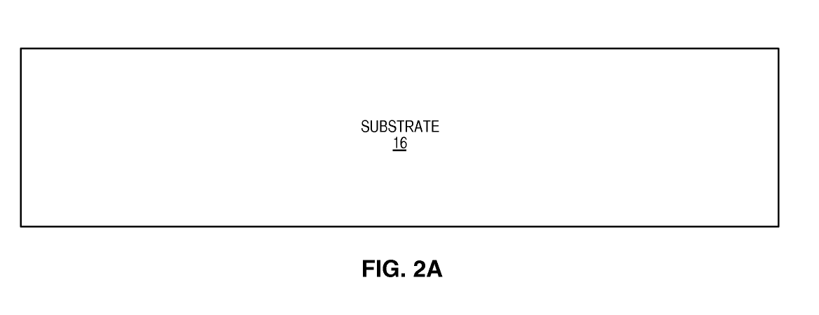

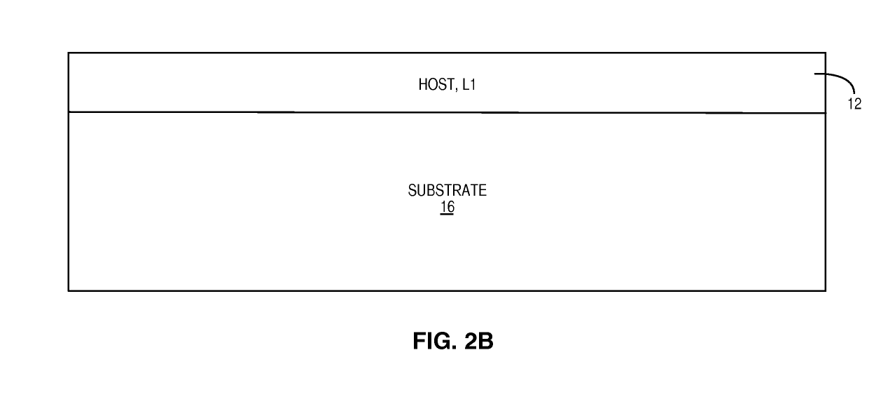

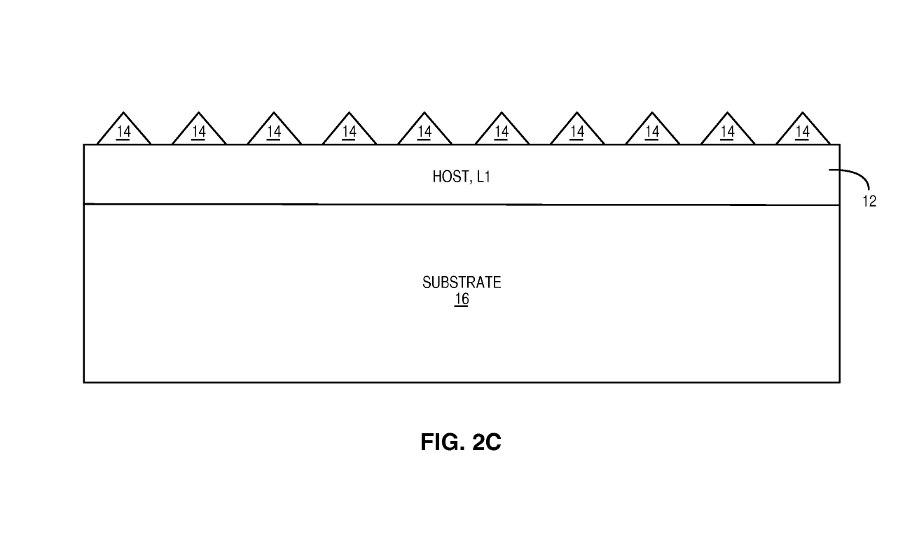

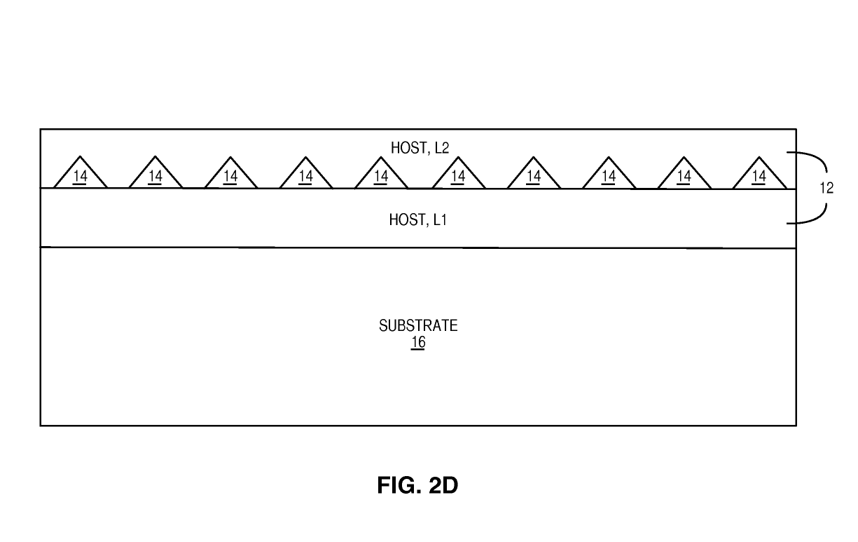

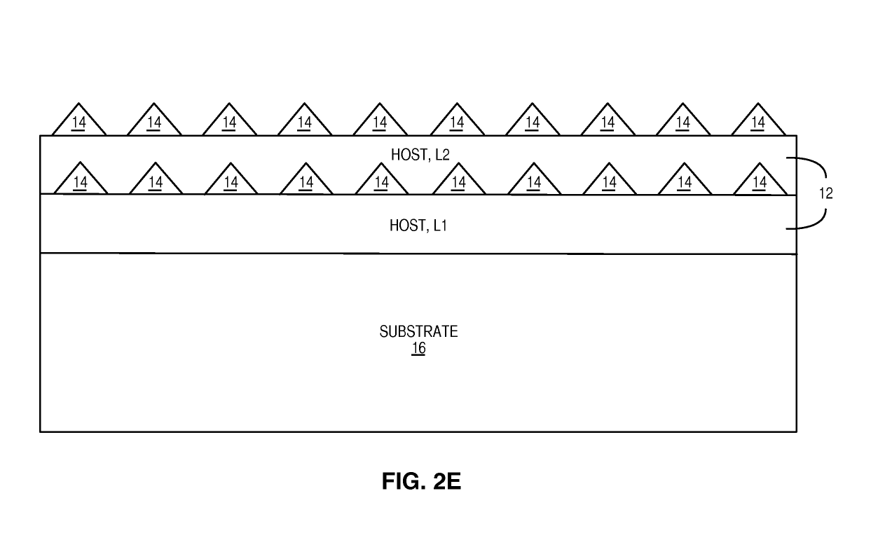

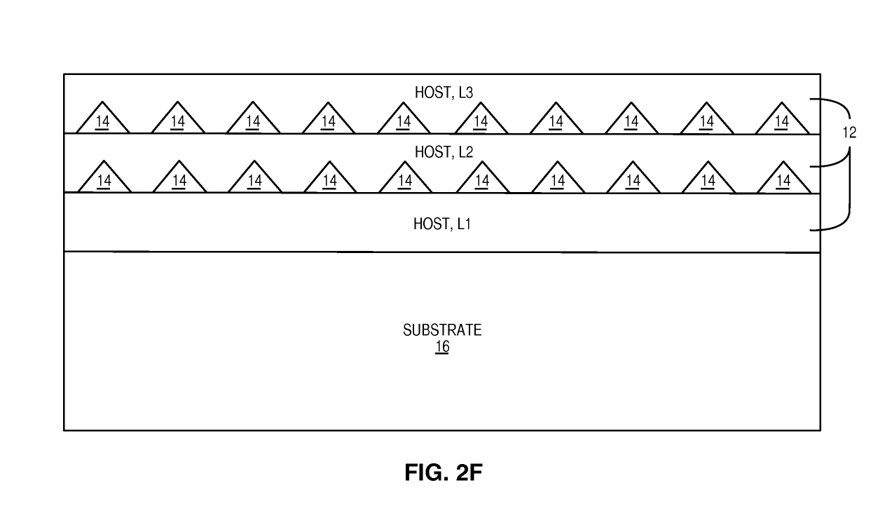

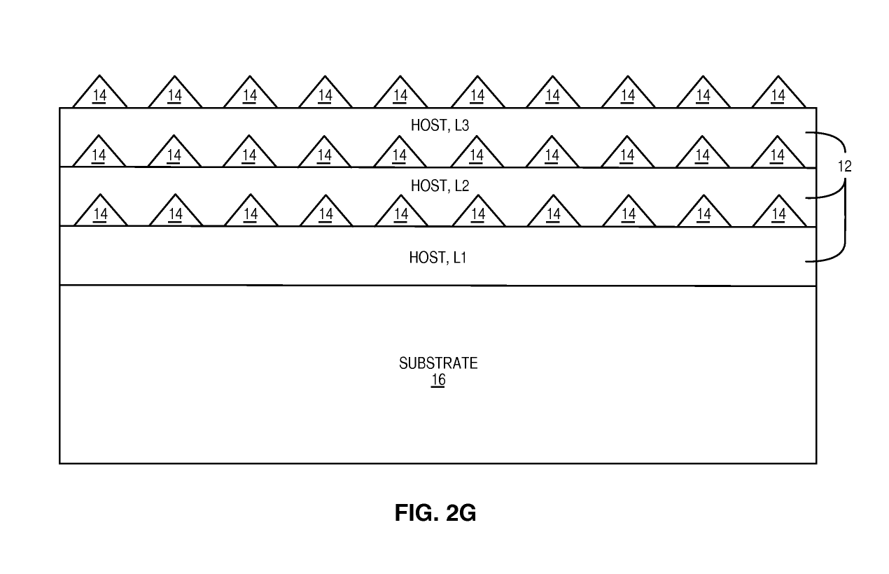

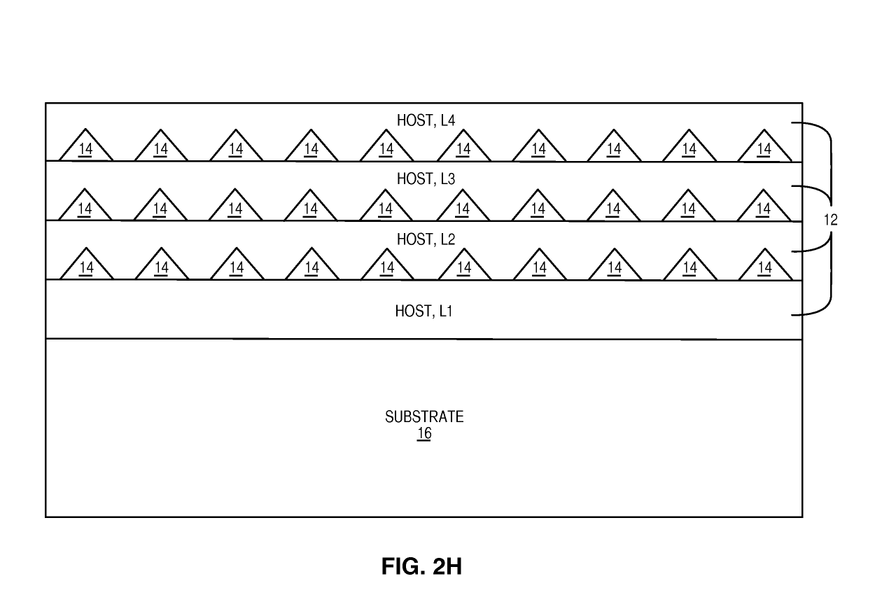

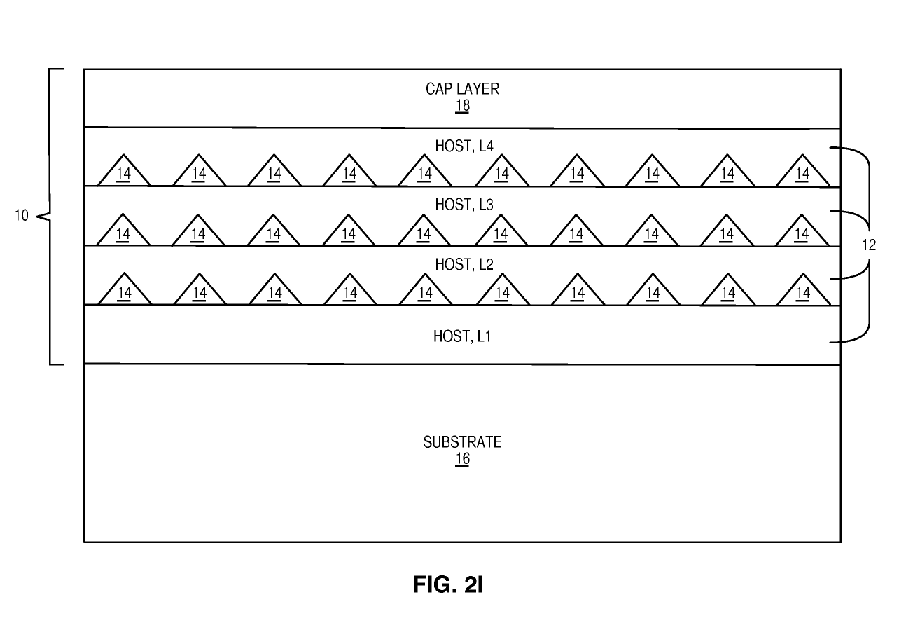

FIGS. 2A through 2I illustrate a process for manufacturing the thermoelectric material 10 of FIG. 1 according to one embodiment of the present disclosure. As illustrated in FIG. 2A, the process begins with the substrate 16. The substrate 16 is treated or pre-processed for a desired crystal orientation, lattice matching, and/or thermal expansion matching. For the lattice mismatch values given in Table 1 above, the substrate 16 is treated or pre-processed for growth of the thermoelectric material 10 in the (001) orientation for hexagonal crystals, such as for the Group V-VI host material 12, or in the (111) orientation for cubic crystals, such as for the nanoinclusions 14. The thermoelectric material 10 is then deposited, or grown, on the substrate 16 using a suitable growth or deposition process such as, but not limited to, MBE, MOCVD, etc. As illustrated in FIG. 2B, a first layer L1 of the Group V-VI host material 12 is formed or deposited on (in some embodiments directly on) the substrate 16. Note that, while not illustrated, there may be additional layers between the substrate 16 and the first layer L1 of the Group V-VI host material 12 (e.g., a nucleation layer). A first layer of the nanoinclusions 14 is then deposited on (in some embodiments directly on) the first layer L1 of the Group V-VI host material 12, as illustrated in FIG. 2C. As illustrated in FIG. 2D, a second layer L2 of the Group V-VI host material 12 is deposited on (in some embodiments directly on) the first layer of the nanoinclusions 14. In this example, since the layers of the nanoinclusions 14 are to form an ordered structure, the thickness of the second layer L2 of the Group V-VI host material 12 is less than a predetermined critical thickness at which the subsequent layer of nanoinclusions 14 would become “free-standing.” In other words, the second layer L2 of the Group V-VI host material 12 is thin enough that the stress induced by the first layer of nanoinclusions 14 will cause the second layer of nanoinclusions 14 to self-align according to the first layer of nanoinclusions 14. This is referred to as “self-assembly.” Note that self-assembly need not be limited to a repeated pattern (e.g., A-A-A) with direct alignment of nanoinclusions 14. Self-assembly may occur in such a way that a complex repeating pattern is achieved such as A-B-A-B, A-B-C-A-B-C, and so forth. Such repeating patterns of self-assembled nanoinclusions 14 are still considered to be ordered. The critical thickness is a function of, e.g., the material used for the Group V-VI host material 12, the material used for the nanoinclusions 14, and the process parameters involved in crystal growth, such as temperature.

Next, the second layer of the nanoinclusions 14 is deposited on (in some embodiments directly on) the second layer L2 of the Group V-VI host material 12, as illustrated in FIG. 2E. As illustrated in FIG. 2F, a third layer L3 of the Group V-VI host material 12 is then deposited on (in some embodiments directly on) the second layer of the nanoinclusions 14. Again, in this example, since the layers of the nanoinclusions 14 are formed an ordered structure, the third layer L3 of the Group V-VI host material 12 is less than the predetermined critical thickness at which the subsequent layer of nanoinclusions 14 would become “free-standing.”

The third layer of the nanoinclusions 14 is then deposited on (in some embodiments directly on) the third layer L3 of the Group V-VI host material 12, as illustrated in FIG. 2G. As illustrated in FIG. 2H, a fourth layer L4 of the Group V-VI host material 12 is then deposited on (in some embodiments directly on) the third layer of the nanoinclusions 14. Lastly, the cap layer 18 is formed on (in some embodiments directly on) the fourth layer L4 of the Group V-VI host material 12, as illustrated in FIG. 2I.

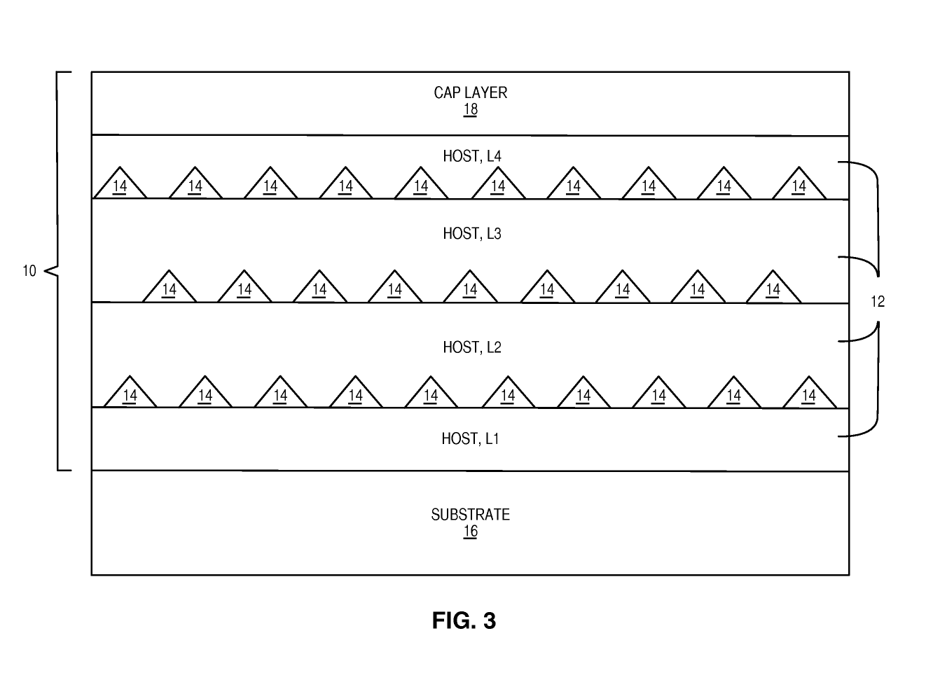

As discussed above, the layers of nanoinclusions 14 in the example of FIG. 1 formed an ordered, or self-aligned, structure of nanoinclusions 14 within the Group V-VI host material 12. FIG. 3 illustrates the thermoelectric material 10 according to another embodiment in which the layers of nanoinclusions 14 form a random, or disordered, structure of nanoinclusions 14. As shown, the nanoinclusions 14 in each of the layers of nanoinclusions 14 are not aligned with the nanoinclusions 14 in the other layers of nanoinclusions 14. In order to achieve the random structure of nanoinclusions 14, the thicknesses of the second and third layers L2 and L3 of the Group V-VI host material 12 are greater than or equal to the predetermined critical thickness. As such, there is no or little stress induced at the surface of, e.g., the second layer L2 of the Group V-VI host material 12 on which the second layer of nanoinclusions 14 is formed due to the first layer of nanoinclusions 14. As a result, there is no self-alignment of the layers of nanoinclusions 14, which in turn results in the random structure of nanoinclusions 14.

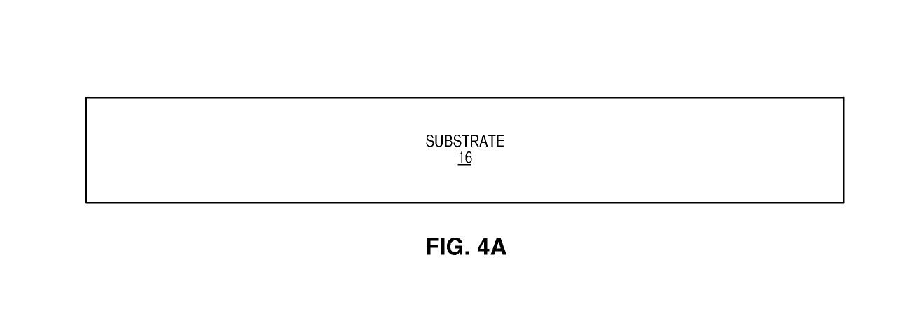

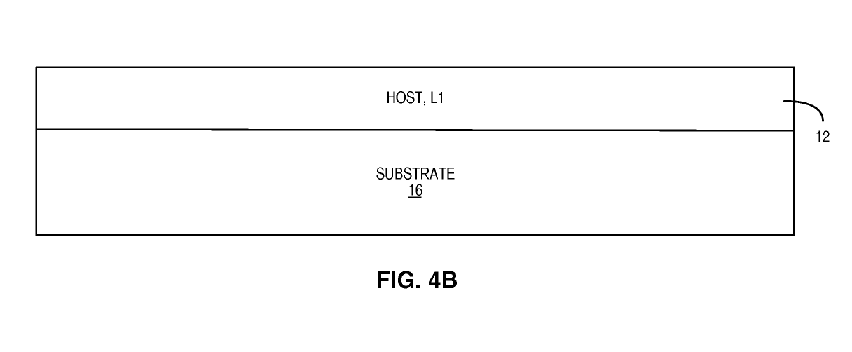

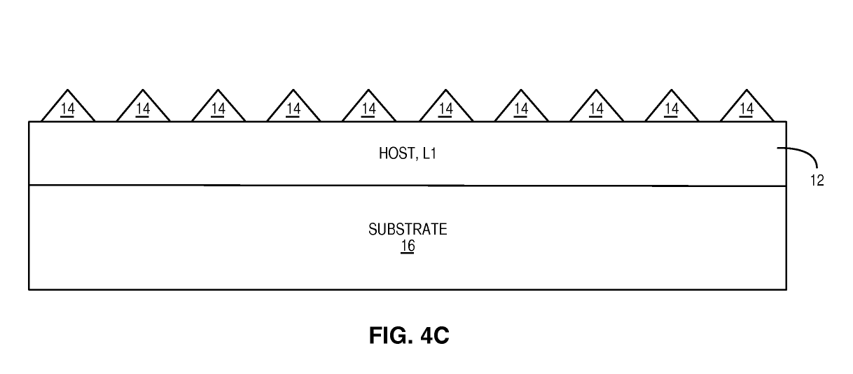

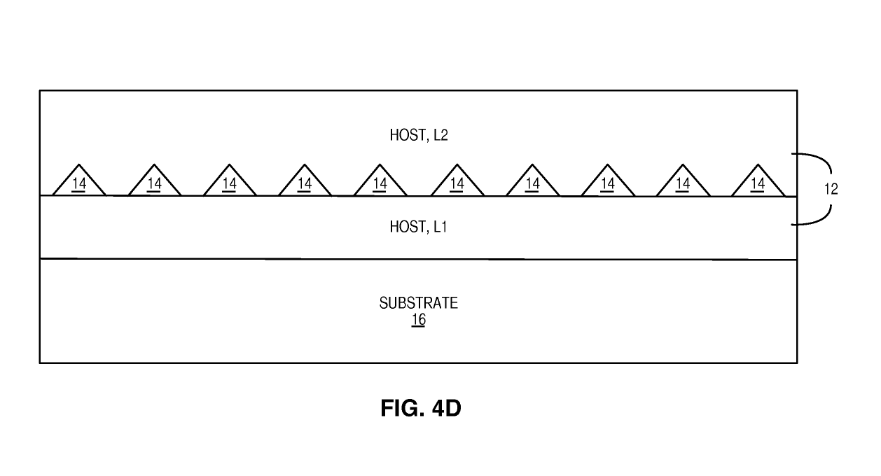

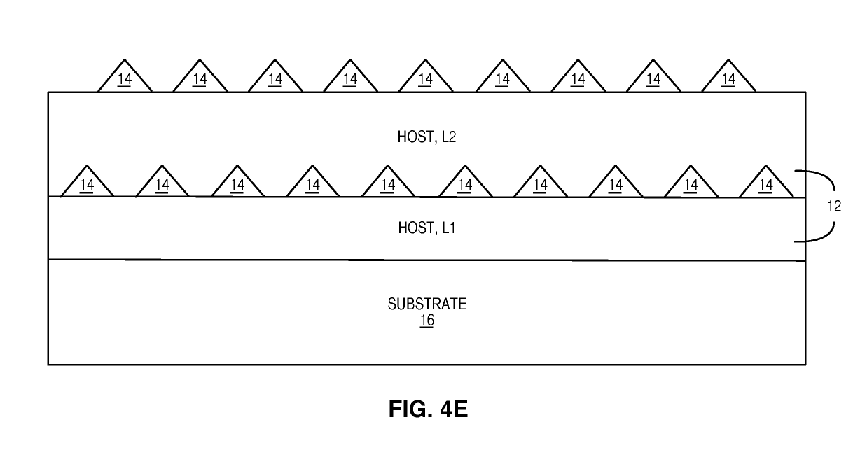

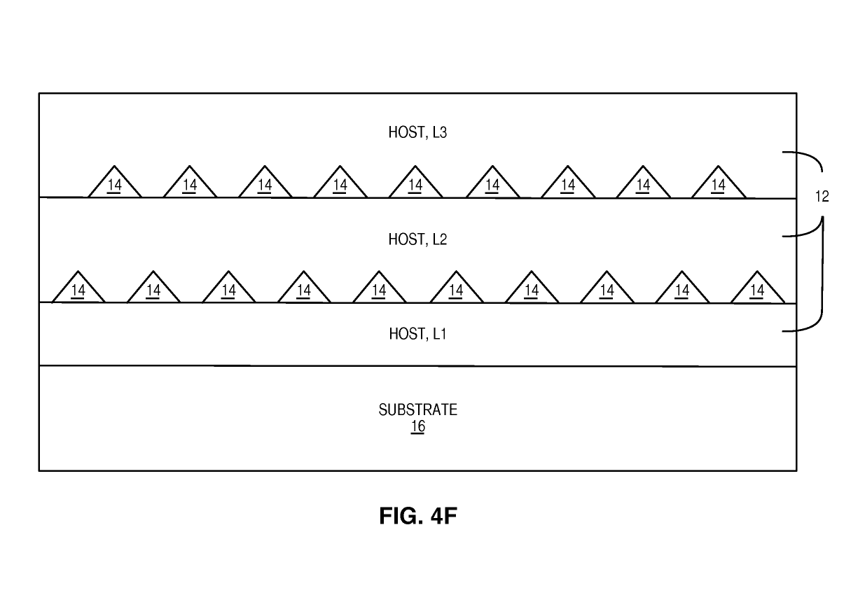

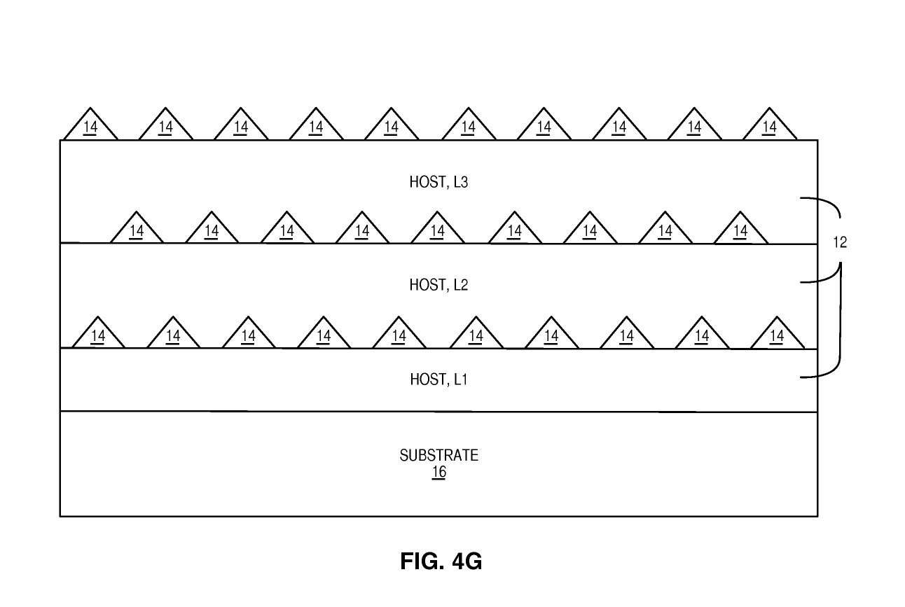

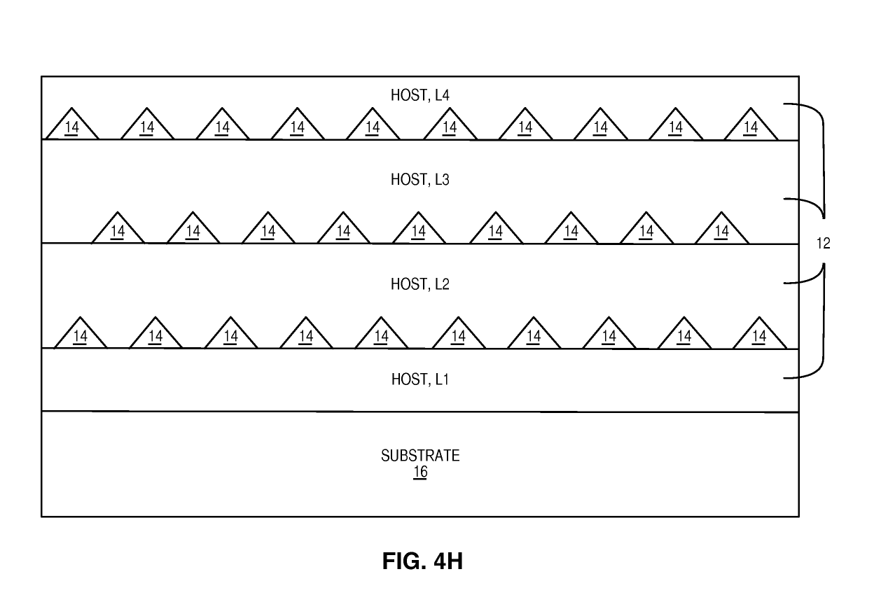

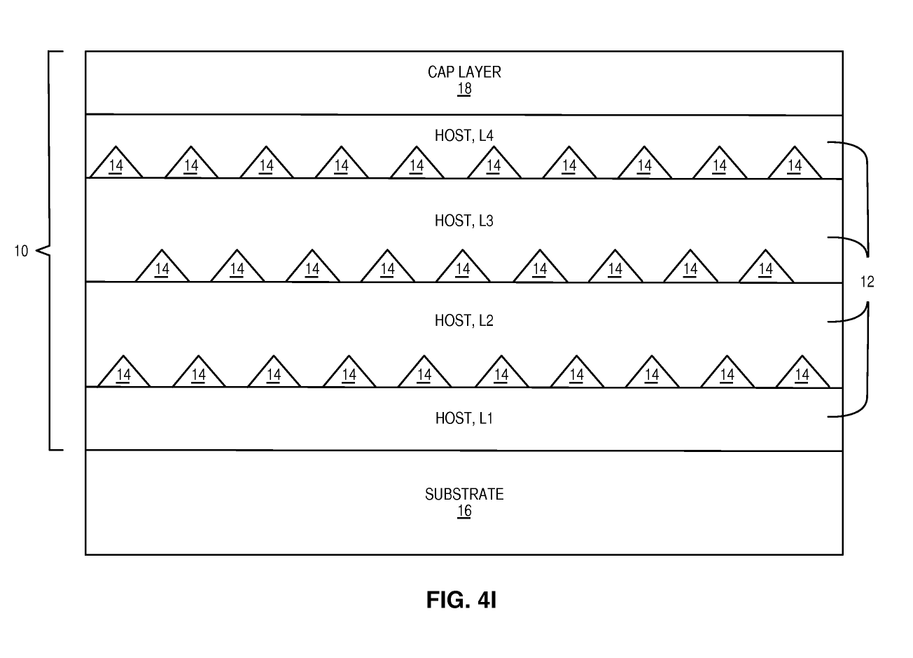

FIGS. 4A through 4I illustrate a process for fabricating the thermoelectric material 10 of FIG. 3 according to one embodiment of the present disclosure. This process is substantially the same as that discussed above with respect to FIGS. 2A through 2I. As illustrated in FIG. 2A, the process begins with the substrate 16. Again, the substrate 16 is treated or pre-processed for a desired crystal orientation, lattice matching, and/or thermal expansion matching. The thermoelectric material 10 is then deposited, or grown, on the substrate 16 using a suitable growth or deposition process such as, but not limited to, MBE, MOCVD, etc. As illustrated in FIG. 4B, a first layer L1 of the Group V-VI host material 12 is formed or deposited on (in some embodiments directly on) the substrate 16. Note that, while not illustrated, there may be additional layers between the substrate 16 and the first layer L1 of the Group V-VI host material 12 (e.g., a nucleation layer).

A first layer of the nanoinclusions 14 is then deposited on (in some embodiments directly on) the first layer L1 of the Group V-VI host material 12, as illustrated in FIG. 4C. As illustrated in FIG. 4D, a second layer L2 of the Group V-VI host material 12 is deposited on (in some embodiments directly on) the first layer of the nanoinclusions 14. In this example, since the layers of the nanoinclusions 14 are to form a random or disordered structure, the thickness of the second layer L2 of the Group V-VI host material 12 is greater than or equal to a predetermined critical thickness at which the subsequent layer of nanoinclusions 14 will become “free-standing.” In other words, the second layer L2 of the Group V-VI host material 12 is thick enough that there any stress induced by the first layer of nanoinclusions 14 is insufficient to cause the second layer of nanoinclusions 14 to self-align with the first layer of nanoinclusions 14.

Next, the second layer of the nanoinclusions 14 is deposited on (in some embodiments directly on) the second layer L2 of the Group V-VI host material 12, as illustrated in FIG. 4E. As illustrated in FIG. 4F, a third layer L3 of the Group V-VI host material 12 is then deposited on (in some embodiments directly on) the second layer of the nanoinclusions 14. Again, in this example, since the layers of the nanoinclusions 14 are to form a random or disordered structure, the third layer L3 of the Group V-VI host material 12 is greater than or equal to the predetermined critical thickness at which the subsequent layer of nanoinclusions 14 will become “free-standing.”

The third layer of the nanoinclusions 14 is then deposited on (in some embodiments directly on) the third layer L3 of the Group V-VI host material 12, as illustrated in FIG. 4G. As illustrated in FIG. 4H, a fourth layer L4 of the Group V-VI host material 12 is then deposited on (in some embodiments directly on) the third layer of the nanoinclusions 14. Lastly, the cap layer 18 is formed on (in some embodiments directly on) the fourth layer L4 of the Group V-VI host material 12, as illustrated in FIG. 4I.

The thermoelectric material 10 disclosed herein provides substantial opportunity for variation. For example, each layer of nanoinclusions 14 may be formed of the same Group III-V or Group IV-VI material. Alternatively, some or all of the layers of nanoinclusions 14 may be formed of different Group III-V or Group IV-VI materials. As another example, the physical properties (e.g., size and/or density) of the nanoinclusions 14 may differ between layers by, e.g., using different Group III-V or Group IV-VI materials. As another example, the thermoelectric material 10 may include additional layers that are not illustrated in the examples of FIGS. 1 and 3. For example, the thermoelectric material 10 may include additional layer(s) of different material(s) disposed above, below, or between the layers of the Group V-VI host material 12 and the nanoinclusions 14.

Those skilled in the art will recognize improvements and modifications to the preferred embodiments of the present disclosure. All such improvements and modifications are considered within the scope of the concepts disclosed herein and the claims that follow.

What is claimed is:

1. A thermoelectric material comprising:
a Group V-VI host material; and
nanoinclusions within the Group V-VI host material, the nanoinclusions comprising one of a group consisting of: Group III-V nanoinclusions and Group IV-VI nanoinclusions.

2. The thermoelectric material of claim 1 wherein the nanoinclusions comprise Group III-V nanoinclusions.

3. The thermoelectric material of claim 1 wherein the nanoinclusions comprise Group IV-VI nanoinclusions.

4. The thermoelectric material of claim 1 wherein the nanoinclusions comprise one of a group consisting of: nanoinclusions of Indium Antimonide (InSb) and nanoinclusions of an alloy of InSb.

5. The thermoelectric material of claim 4 wherein the nanoinclusions comprise nanoinclusions of the alloy of InSb, and the alloy of InSb is In_{1-X}Ga_{X}Sb, where 0<X<1.

6. The thermoelectric material of claim 1 wherein the nanoinclusions comprise one of a group consisting of: nanoinclusions of Lead Telluride (PbTe) and nanoinclusions of an alloy of PbTe.

7. The thermoelectric material of claim 6 wherein the nanoinclusions comprise nanoinclusions of the alloy of PbTe, and the alloy of PbTe is one of a group consisting of: PbTe_{1-X}Se_{X}, Pb_{1-X}Ge_{X}Te_{Y}Se_{1-Y, Pb}_{1-X}Sn_{X}Te_{Y}Se_{1-Y}, and Pb_{1-X}Sr_{X}Te_{Y}Se_{1-Y}, where 0<X<1 and where 0<Y<1.

8. The thermoelectric material of claim 1 wherein the Group V-VI host material is one of a group consisting of: Bismuth Selenide (Bi₂Te₃) or an alloy of Bi₂Te₃.

9. The thermoelectric material of claim 8 wherein the nanoinclusions comprise one of a group consisting of: nanoinclusions of Indium Antimonide (InSb) and nanoinclusions of an alloy of InSb.

10. The thermoelectric material of claim 8 wherein the nanoinclusions comprise one of a group consisting of: nanoinclusions of Lead Telluride (PbTe) and nanoinclusions of an alloy of PbTe.

11. The thermoelectric material of claim 1 wherein the Group V-VI host material is one of a group consisting of: Antimony Telluride (Sb₂Te₃) or an alloy of Sb₂Te₃.

12. The thermoelectric material of claim 11 wherein the nanoinclusions comprise one of a group consisting of: nanoinclusions of Indium Antimonide (InSb) and nanoinclusions of an alloy of InSb.

13. The thermoelectric material of claim 11 wherein the nanoinclusions comprise one of a group consisting of: nanoinclusions of PbTe and nanoinclusions of an alloy of PbTe.

14. The thermoelectric material of claim 1 wherein the Group V-VI host material is one of a group consisting of: Bi_{X}Sb_{2-X}Te₃ or an alloy of Bi_{X}Sb_{2-X}Te₃.

15. The thermoelectric material of claim 14 wherein the nanoinclusions comprise one of a group consisting of: nanoinclusions of Indium Antimonide (InSb) and nanoinclusions of an alloy of InSb.

16. The thermoelectric material of claim 14 wherein the nanoinclusions comprise one of a group consisting of: nanoinclusions of Lead Telluride (PbTe) and nanoinclusions of an alloy of PbTe.

17. The thermoelectric material of claim 1 wherein the Group V-VI host material is one of a group consisting of: Bi₂Te_{3-X}Se_{X} or an alloy of Bi₂Te_{3-X}Se_{X}.

18. The thermoelectric material of claim 17 wherein the nanoinclusions comprise one of a group consisting of: nanoinclusions of Indium Antimonide (InSb) and nanoinclusions of an alloy of InSb.

19. The thermoelectric material of claim 17 wherein the nanoinclusions comprise one of a group consisting of: nanoinclusions of Lead Telluride (PbTe) and nanoinclusions of an alloy of PbTe.

20. The thermoelectric material of claim 1 wherein a lattice mismatch between the Group V-VI host material and a material used for the nanoinclusions is greater than 4%.

21. The thermoelectric material of claim 1 wherein a lattice mismatch between the Group V-VI host material and a material used for the nanoinclusions is greater than 5%.

22. The thermoelectric material of claim 1 wherein a lattice mismatch between the Group V-VI host material and a material used for the nanoinclusions is greater than 6%.

23. The thermoelectric material of claim 1 wherein a lattice mismatch between the Group V-VI host material and a material used for the nanoinclusions is greater than 7%.

24. The thermoelectric material of claim 1 wherein the nanoinclusions form a random structure within the Group V-VI host material.

25. The thermoelectric material of claim 1 wherein the nanoinclusions form an ordered structure within the Group V-VI host material.

26. A method of fabricating a thermoelectric material, comprising:
providing a first layer of a Group V-VI host material;
depositing a layer of nanoinclusions on a surface of the first layer of the Group V-VI host material, the nanoinclusions comprising one of a group consisting of: Group III-V nanoinclusions and Group IV-VI nanoinclusions; and
depositing a second layer of the Group V-VI host material over the layer of nanoinclusions.

27. The method of claim 26 further comprising:
depositing a second layer of nanoinclusions on a surface of the second layer of the Group V-VI host material; and
depositing a third layer of the Group V-VI host material over the second layer of nanoinclusions.

28. The method of claim 26 wherein the nanoinclusions comprise one of a group consisting of: nanoinclusions of Indium Antimonide (InSb) and nanoinclusions of an alloy of InSb.

29. The method of claim 28 wherein the Group V-VI host material is one of a group consisting of: Bismuth Telluride (Bi₂Te₃), an alloy of Bi₂Te₃, Antimony Telluride (Sb₂Te₃), an alloy of Sb₂Te₃, Bi_{X}Sb_{2-X}Te₃, an alloy of Bi_{X}Sb_{2-X}Te₃, Bi₂Te_{3-X}Se_{X}, and an alloy of Bi₂Te_{3-X}Se_{X}.

30. The method of claim 26 wherein the nanoinclusions comprise one of a group consisting of: nanoinclusions of Lead Telluride (PbTe) and nanoinclusions of an alloy of PbTe.

31. The method of claim 30 wherein the Group V-VI host material is one of a group consisting of: Bismuth Telluride (Bi₂Te₃), an alloy of Bi₂Te₃, Antimony Telluride (Sb₂Te₃), an alloy of Sb₂Te₃, Bi_{X}Sb_{2-X}Te₃, an alloy of Bi_{X}Sb_{2-X}Te₃, Bi₂Te_{3-X}Se_{X}, and an alloy of Bi₂Te_{3-X}Se_{X}.
